(19) United States
(12) Patent Application Publication
(10) Pub. No.: US 2025/0201688 A1
(43) Pub. Date: Jun. 19, 2025

(54) INTEGRATED PASSIVE COMPONENT, AND MANUFACTURING METHOD FOR INTEGRATED PASSIVE COMPONENT

(71) Applicant: Murata Manufacturing Co., Ltd., Kyoto-fu (JP)

(72) Inventor: Jyou KIKURA, Nagaokakyo-shi (JP)

(73) Assignee: Murata Manufacturing Co., Ltd., Kyoto-fu (JP)

(21) Appl. No.: 19/063,571

(22) Filed: Feb. 26, 2025

Related U.S. Application Data
(63) Continuation of application No. PCT/JP2023/039618, filed on Nov. 2, 2023.

(30) Foreign Application Priority Data
Nov. 8, 2022 (JP) 2022-178816

(51) Int. Cl. H01L 23/498; H01L 23/522; H03H 7/01; H05K 1/16

(52) U.S. Cl. CPC H01L 23/49822; H01L 23/5223; H01L 23/5227; H03H 7/0115; H05K 1/162

(57) ABSTRACT

An integrated passive component has upper and lower surfaces facing in mutually opposite directions. The integrated passive component includes an insulating film having a first surface facing in the same direction as the upper surface and a second surface facing in the same direction as the lower surface; a capacitor in the insulating film; and a multilayer wiring structure on the first surface. The multilayer wiring structure includes resin layers and wiring layers, the resin and wiring layers being alternately stacked, each of the wiring layers includes wiring lines, and at least a portion of the wiring lines constitutes an inductor. The insulating film includes an inorganic material layer made of an inorganic insulating material, and a thickness of the inorganic material layer is smaller than a sum of a thickness of each of the resin layers. The second surface of the insulating film constitutes the lower surface.

### CROSS-REFERENCE TO RELATED APPLICATIONS

This application claims benefit of priority to International Patent Application No. PCT/JP2023/039618, filed Nov. 2, 2023, and to Japanese Patent Application No. 2022-178816, filed Nov. 8, 2022, the entire contents of each are incorporated herein by reference.

### BACKGROUND

### Technical Field

The present disclosure relates to an integrated passive component and a method of manufacturing an integrated passive component.

### Background Art

An integrated passive component in which a smoothing layer is disposed on a substrate and a capacitor and an inductor are disposed on the smoothing layer is known as described, for example, in International Publication No. 2021/193132. The inductor is composed of a plurality of wiring lines of a multilayer wiring structure in which a plurality of resin layers and the plurality of wiring lines are alternately stacked. Examples of the material used for the substrate include silicon single crystal, alumina, sapphire, aluminum nitride, MgO single crystal, SrTiO₃ single crystal, surface silicon oxide, glass, quartz, ferrite, and the like.

### SUMMARY

In the integrated passive component, thickening and multilayering of the wiring lines, which constitute the inductor, and the resin layers are required to improve electrical characteristics. When the wiring lines and resin layers become thicker, cracks are likely to occur in the resin layers due to thermal stress caused by the difference in the coefficient of linear expansion between the resin layers and the substrate. Further, peeling is likely to occur at the interface between the resin layers and the smoothing layer. When the cracks and peeling occur, moisture resistance is reduced. In order to prevent the cracks and peeling from occurring, the thickness of the resin layer and the number of stacked layers are limited, so that the improvement in the electrical characteristics of the integrated passive component is limited.

Accordingly, the present disclosure provides an integrated passive component in which the cracks and peeling due to the thermal stress are less likely to occur, and a method of manufacturing such an integrated passive component.

According to an aspect of the present disclosure, an integrated passive component having an upper surface and a lower surface facing in mutually opposite directions is provided. The integrated passive component includes an insulating film having a first surface and a second surface, the first surface facing in the same direction as the upper surface, the second surface facing in the same direction as the lower surface; a capacitor disposed in the insulating film; and a multilayer wiring structure disposed on the first surface of the insulating film. The multilayer wiring structure includes a plurality of resin layers and a plurality of wiring layers, the plurality of resin layers and the plurality of wiring layers being alternately stacked, each of the plurality of wiring layers includes a plurality of wiring lines, and at least a portion of the plurality of wiring lines constitutes an inductor. The insulating film includes an inorganic material layer made of an inorganic insulating material, and a thickness of the inorganic material layer is smaller than a sum of a thickness of each of the plurality of resin layers of the multilayer wiring structure. The second surface of the insulating film constitutes the lower surface.

According to another aspect of the present disclosure, an integrated passive component having an upper surface and a lower surface facing in mutually opposite directions is provided. The integrated passive component includes an insulating film having a first surface and a second surface, the first surface facing in the same direction as the upper surface, the second surface facing in the same direction as the lower surface; a capacitor disposed in the insulating film; a multilayer wiring structure disposed on the first surface of the insulating film; and a supporting member made of an insulating resin and attached to the second surface of the insulating film. The multilayer wiring structure includes a plurality of resin layers and a plurality of wiring layers, the plurality of resin layers and the plurality of wiring layers being alternately stacked, each of the plurality of wiring layers includes a plurality of wiring lines, and at least a portion of the plurality of wiring lines constitutes an inductor. The insulating film includes an inorganic material layer made of an inorganic insulating material, and a thickness of the inorganic material layer is smaller than a sum of a thickness of each of the plurality of resin layers of the multilayer wiring structure.

According to further another aspect of the present disclosure, a method of manufacturing an integrated passive component is provided. The method includes forming a lower insulating film on one surface of a temporary substrate made of a semiconductor; forming a capacitor on a portion of a region of the lower insulating film; forming an upper insulating film on the lower insulating film so as to cover the capacitor; forming a multilayer wiring structure on the upper insulating film, the multilayer wiring structure including a plurality of resin layers and a plurality of wiring lines constituting an inductor, the plurality of resin layers and the plurality of wiring lines being alternately stacked; and removing the temporary substrate to expose the lower insulating film.

Since the thickness of the inorganic material layer is smaller than the sum of the thickness of each of the plurality of resin layers of the multilayer wiring structure, the generation of thermal stress can be suppressed. Further, since resin is used for the supporting member, the difference in the coefficient of linear expansion between the supporting member and each of the plurality of resin layers of the multilayer wiring structure is small. Therefore, the generation of thermal stress can be suppressed. Thus, the generation of the cracks and peeling due to the thermal stress can be suppressed.

### BRIEF DESCRIPTION OF THE DRAWINGS

FIG. 1A is a diagram showing the shape and positional relationship of each of the components of an integrated passive component according to a first embodiment in plan view, and FIG. 1B is an equivalent circuit diagram of the integrated passive component according to the first embodiment;

FIG. 2 is a cross-sectional view taken along a dot-dashed line 2-2 of FIG. 1A;

FIGS. 3A to 3C are each a cross-sectional view of the integrated passive component according to the first embodiment at an intermediate stage of manufacture;

FIGS. 4A to 4C are each a cross-sectional view of the integrated passive component according to the first embodiment at an intermediate stage of manufacture;

FIGS. 5A and 5B are each a cross-sectional view of the integrated passive component according to the first embodiment at an intermediate stage of manufacture;

FIGS. 6A and 6B are each a cross-sectional view of the integrated passive component according to the first embodiment at an intermediate stage of manufacture;

FIG. 7 is a cross-sectional view of the integrated passive component according to the first embodiment at an intermediate stage of manufacture;

FIG. 8 is a cross-sectional view of an integrated passive component according to a second embodiment;

FIG. 9 is a cross-sectional view of an integrated passive component according to a third embodiment; and

FIG. 10A is a diagram showing the shape and positional relationship of each of the components of an integrated passive component according to a fourth embodiment in plan view, and FIG. 10B is an equivalent circuit diagram of the integrated passive component according to the fourth embodiment.

### DETAILED DESCRIPTION

### First Embodiment

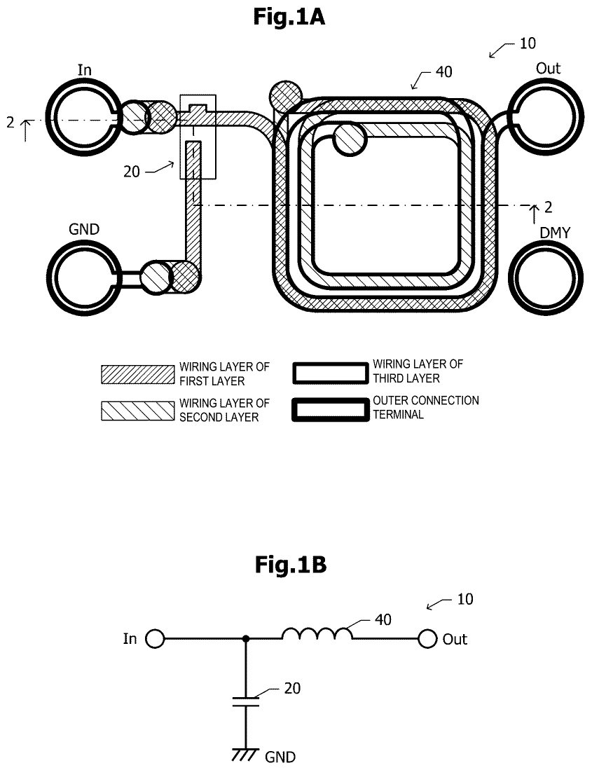

An integrated passive component according to a first embodiment and a method of manufacturing the integrated passive component will be described with reference to FIGS. 1A to 7.

FIG. 1A is a diagram showing the shape and positional relationship of each of the components of an integrated passive component 10 according to the first embodiment in plan view, and FIG. 1B is an equivalent circuit diagram of the integrated passive component 10 according to the first embodiment. The integrated passive component 10 according to the first embodiment has a capacitor 20, an inductor 40, an input terminal In, an output terminal Out, a ground terminal GND, and a dummy terminal DMY, all these components being provided on a common insulating film.

As shown in FIG. 1B, the inductor 40 is connected between the input terminal In and the output terminal Out, and the capacitor 20 is connected between the input terminal In and the ground terminal GND. The integrated passive component 10 according to the first embodiment functions as a low pass filter.

As shown in FIG. 1A, the integrated passive component 10 according to the first embodiment includes three wiring layers from a first layer to a third layer. A plurality of outer connection terminals such as the input terminal In, the output terminal Out, and the ground terminal GND are disposed on the wiring layer of the third layer. In FIG. 1A, each wiring line of the wiring layer of the first layer is indicated by relatively dense hatching slanted right upward, and each wiring line of the wiring layer of the second layer is indicated by relatively thin hatching slanted right downward. The outlines of the outer connection terminals are indicated by the thickest solid lines, and the outline of each wiring line of the wiring layer of the third layer is indicated by a second thickest solid line.

In the wiring line of the first layer, the wiring line of the second layer, and the wiring line of the third layer that constitute the inductor 40, the wiring line of the first layer is made approximately one turn along a square outer peripheral line, the wiring line of the second layer has a spiral shape with a turn number of turns of approximately 2, and the wiring line of the third layer has a spiral shape with a number of turns of approximately 1+¾. The wiring lines from the first layer to the third layer are connected in series to thereby form the inductor 40 with a number of turns of approximately 4+¾. One end portion of the wiring line of the first layer is connected to the input terminal In via the wiring lines of the second layer and third layer, and the output terminal Out is connected to one end portion of the wiring line of the third layer.

Further, one electrode of the capacitor 20 is connected to the one end portion of the wiring line of the first layer. The other electrode of the capacitor 20 is connected to the ground terminal GND via the wiring lines from the first layer to the third layer.

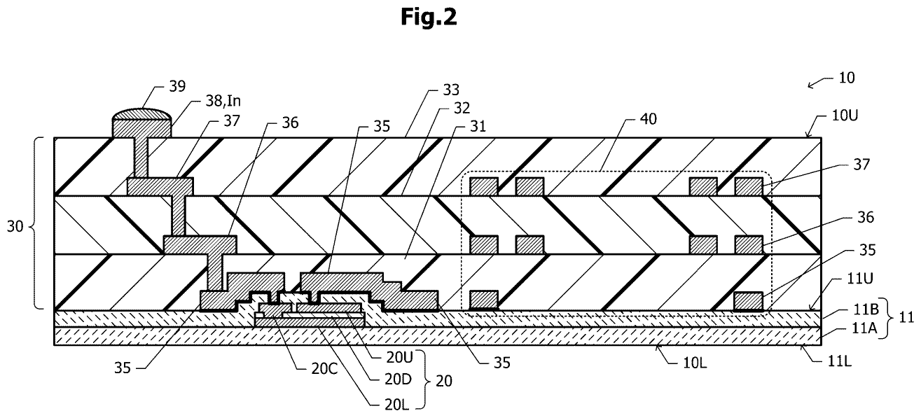

FIG. 2 is a cross-sectional view taken along a dot-dashed line 2-2 of FIG. 1A. The integrated passive component 10 according to the first embodiment has an upper surface 10U and a lower surface 10L facing in mutually opposite directions. The integrated passive component 10 includes an insulating film 11 and a multilayer wiring structure 30. The insulating film 11 has a first surface 11U facing in the same direction as the upper surface 10U of the integrated passive component 10, and a second surface 11L facing in the same direction as the lower surface 10L of the integrated passive component 10. The multilayer wiring structure 30 is disposed on the first surface 11U of the insulating film 11. The lower surface 10L of the integrated passive component 10 and the second surface 11L of the insulating film 11 are the same surface, and the second surface 11L of the insulating film 11 constitutes the lower surface 10L of the integrated passive component 10.

The capacitor 20 is disposed in the insulating film 11. Next, the configurations of the insulating film 11 and the capacitor 20 will be described. The insulating film 11 includes a lower insulating film 11A having the second surface 11L, and an upper insulating film 11B disposed on the lower insulating film 11A and having the first surface 11U. The capacitor 20 is disposed between the lower insulating film 11A and the upper insulating film 11B. For example, the capacitor 20 is disposed on a portion of the region of the upper surface of the lower insulating film 11A, and the upper insulating film 11B covers the capacitor 20. Each of the lower insulating film 11A and the upper insulating film 11B is formed of an inorganic insulating material such as silicon oxide, silicon nitride, or the like.

The capacitor 20 includes a lower electrode layer 20L, a capacitor dielectric film 20D, and an upper electrode layer 20U stacked in this order on the lower insulating film 11A. A portion of the capacitor dielectric film 20D is provided with an opening, and a contact electrode 20C disposed on the capacitor dielectric film 20D is connected to the lower electrode layer 20L through the opening. Note that the present disclosure may include a configuration in which the capacitor dielectric film 20D is not provided with an opening. In such a case, two conductor patterns disposed on the capacitor dielectric film 20D constitute a pair of electrodes of the capacitor 20.

The multilayer wiring structure 30 includes a plurality of resin layers and a plurality of wiring layers, the resin layers and the wiring layers being alternately stacked. The integrated passive component 10 according to the first embodiment includes three resin layers 31, 32 and 33 and three wiring layers. A plurality of wiring lines 35 are disposed in the wiring layer of the first layer, a plurality of wiring lines 36 are disposed in the wiring layer of the second layer, and a plurality of wiring lines 37 are disposed in the wiring layer of the third layer. Note that the present disclosure may include a configuration in which the multilayer structure includes two layers, four layers or more than four layers according to necessity.

The two resin layers 31 and 32 exist between the two layers of wiring lines 35 and 36 vertically adjacent to each other and between the two layers of wiring lines 36 and 37 vertically adjacent to each other, respectively, among the wiring lines 35, 36 and 37 of the plurality of wiring layers; and the resin layer 31 and the resin layer 32 contact each other in a region where the wiring line 36 is not disposed. The resin layer 33 exists between the wiring line 37 of the uppermost wiring layer and outer connection terminals 38, and the resin layer 32 and the resin layer 33 contact each other in a region where the wiring line 37 is not disposed. In the region where the two vertically adjacent resin layers contact each other, the interface between the two resin layers does not have to be clearly observed in some cases. The multilayer wiring structure 30 may include at least one of a resin layer disposed between the wiring lines 35 of the lowermost wiring layer and the insulating film 11 constituting the underlayer of the wiring lines 35, and a resin layer covering the outer connection terminals 38 and the surface of the resin layer 33 constituting the underlayer of the outer connection terminals 38.

The plurality of outer connection terminals 38 are disposed on the uppermost resin layer 33. Solders 39 are placed on the outer connection terminals 38. The outer connection terminals 38 are connected to the wiring lines 37, which are the layer below the outer connection terminals 38, through via holes formed in the resin layer 33. A part of the plurality of wiring lines of the multilayer wiring structure 30 constitutes the inductor 40. The wiring lines 35, 36 and 37 constituting the inductor 40 are disposed over the three wiring layers from the first layer to the third layer.

One of the wiring lines 35 of the first layer is connected to the upper electrode layer 20U of the capacitor 20 through an opening formed in the upper insulating film 11B, and another one of the wiring lines 35 of the first layer is connected to the contact electrode 20C through an opening formed in the upper insulating film 11B, and is connected to the lower electrode layer 20L of the capacitor 20 via the contact electrode 20C.

The input terminal In, which is one of the plurality of outer connection terminals 38, is connected to the lower electrode layer 20L of the capacitor 20 via the wiring lines 37, 36 and 35 of each wiring layer and the contact electrode 20C. Although not shown in the cross-sectional view shown in FIG. 2, the outer connection terminals such as the output terminal Out, the ground terminal GND, and the dummy terminal DMY are disposed on the resin layer 33, as shown in FIG. 1A.

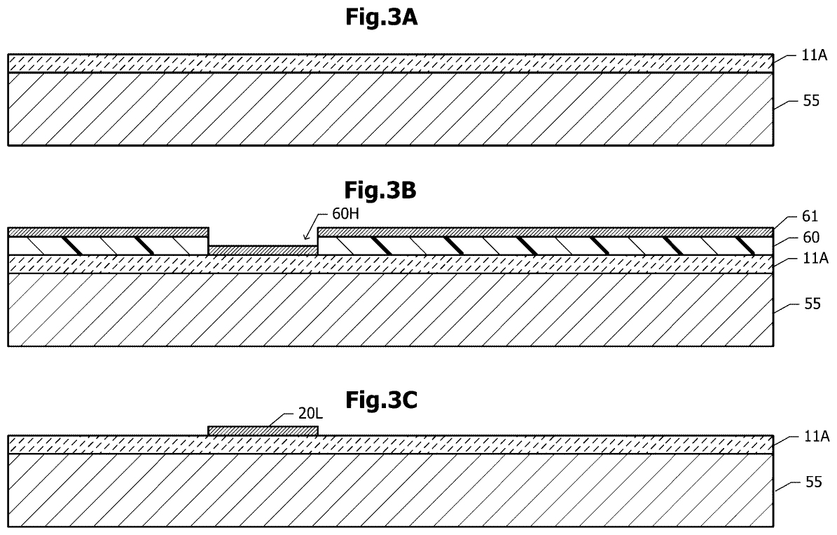

Next, a method of manufacturing the integrated passive component 10 according to the first embodiment will be described with reference to FIGS. 3A to 7. Each of FIGS. 3A to 7 is a cross-sectional view of the integrated passive component 10 according to the first embodiment at an intermediate stage of manufacture.

As shown in FIG. 3A, the lower insulating film 11A is formed on one surface (hereinafter sometimes referred to as “upper surface”) of a temporary substrate 55 made of a semiconductor. A silicon substrate, for example, is used as the temporary substrate 55. The lower insulating film 11A is formed of an inorganic insulating material. For example, a material containing silicon and oxygen as constituent elements (for example, silicon oxide) or a material containing silicon and nitrogen as constituent elements (for example, silicon nitride) is used for the lower insulating film 11A. The lower insulating film 11A is formed by, for example, sputtering, plasma chemical vapor deposition (plasma CVD), metal organic chemical vapor deposition (MOCVD), or the like. Note that the silicon oxide or silicon nitride constituting the lower insulating film 11A may contain impurities.

As shown in FIG. 3B, a photoresist film 60 is formed on the lower insulating film 11A, and an opening 60H is formed in a region where the lower electrode layer 20L (see FIG. 2) of the capacitor 20 is to be formed. A conductor film 61 is formed on the lower insulating film 11A exposed on the bottom surface of the opening and on the photoresist film 60. Cu or an alloy containing Cu as a main component, for example, is used for the conductor film 61, and the conductor film 61 is formed by, for example, vacuum evaporation.

As shown in FIG. 3C, the photoresist film 60 and the conductor film 61 deposited on the photoresist film 60 (see FIG. 3B) are removed. Thus, the lower electrode layer 20L of the capacitor 20 is left on the lower insulating film 11A.

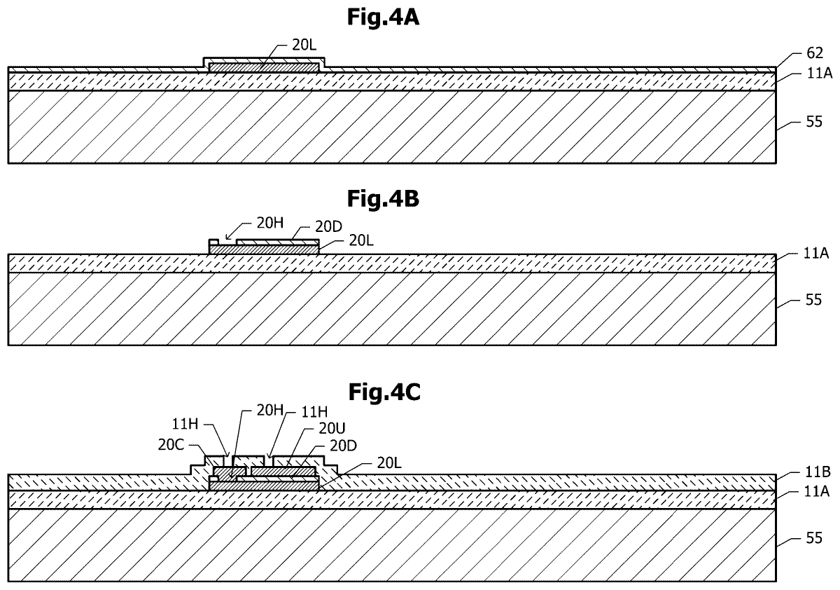

As shown in FIG. 4A, a dielectric film 62 is formed so as to cover the lower electrode layer 20L and the exposed surface of the lower insulating film 11A. For example, a dielectric material such as silicon oxide or silicon nitride is used for the dielectric film 62. The dielectric film 62 is formed by, for example, sputtering, plasma CVD, MOCVD, or the like.

As shown in FIG. 4B, when the upper surface of the temporary substrate 55 is viewed in plan view (hereinafter sometimes simply referred to as “in plan view”), an opening 20H passing through the dielectric film 62 is formed at a place overlapping a portion of the lower insulating film 11A. At this time, an unnecessary portion of the dielectric film 62 (see FIG. 4A) (i.e., the portion deposited on the lower insulating film 11A) may be removed. The capacitor dielectric film 20D formed by a portion of the dielectric film 62 (see FIG. 4A) is left on the lower electrode layer 20L.

As shown in FIG. 4C, the upper electrode layer 20U and the contact electrode 20C are formed on the capacitor dielectric film 20D. The contact electrode 20C is connected to the lower electrode layer 20L through the opening 20H provided in the capacitor dielectric film 20D. The method of forming the upper electrode layer 20U and the contact electrode 20C is the same as the method of forming the lower electrode layer 20L.

The upper insulating film 11B is formed on the lower insulating film 11A so as to cover the upper electrode layer 20U and the contact electrode 20C. An inorganic insulating material such as silicon oxide or silicon nitride is used for the upper insulating film 11B, and the upper insulating film 11B is formed by the same method as the method of forming the lower insulating film 11A. Note that the silicon oxide or silicon nitride constituting the upper insulating film 11B may contain impurities. Openings 11H are formed in the upper insulating film 11B to expose a portion of each of the upper electrode layer 20U and the contact electrode 20C.

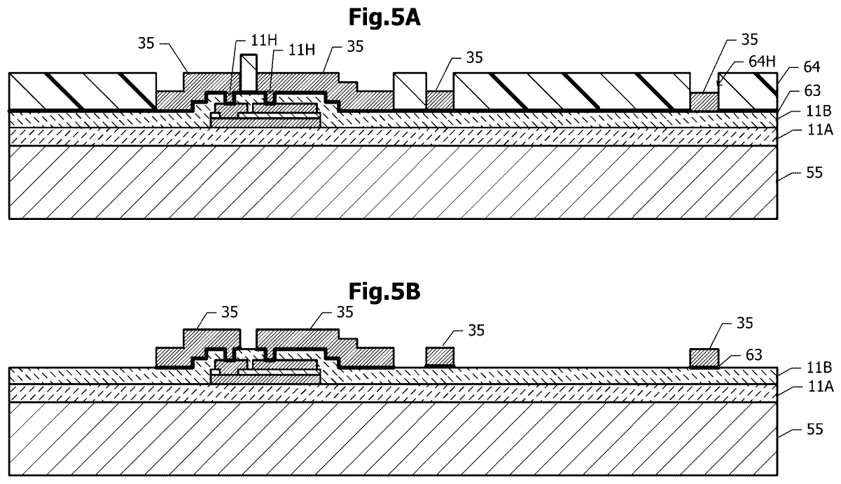

As shown in FIG. 5A, a metal film 63 is formed to cover the upper insulating film 11B. The metal film 63 also covers the bottom surface and side surface of the openings 11H formed in the upper insulating film 11B. The metal film 63 is composed of 2 layers, which are a Ti layer and a Cu layer disposed on the Ti layer. The metal film 63 is formed by, for example, sputtering.

A photoresist film 64 is formed on the metal film 63, and openings 64H are formed in regions where the wiring lines 35 of the first layer are to be formed. Cu is deposited by an electroplating method using the metal film 63 as a seed layer. Thus, the wiring lines 35 of the first layer are formed in the openings 64H.

As shown in FIG. 5B, the photoresist film 64 (see FIG. 5A) is removed. Thus, a portion of the metal film 63 (see FIG. 5A) is exposed. The exposed metal film 63 is removed by wet etching. The metal film 63 used as the seed layer is left between the wiring lines 35 of the first layer and the upper insulating film 11B. Such a method of forming the wiring lines 35 is called a semi-additive method.

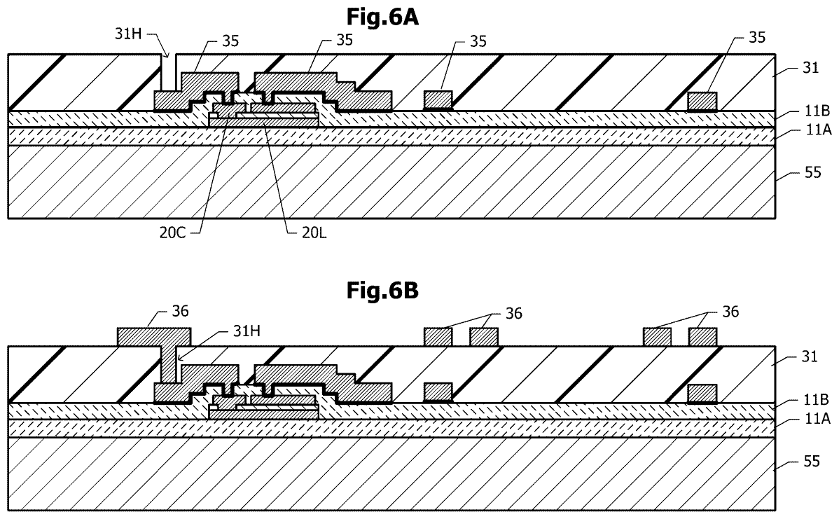

As shown in FIG. 6A, the resin layer 31 of the first layer is formed on the wiring lines 35 of the first layer and the upper insulating film 11B. The resin layer 31 may be formed by bonding a semi-cured resin film mixed with a photosensitive material using a vacuum laminating method. For example, an epoxy resin film or a polyimide resin film is used as the resin film. Although the surface of the underlayer of the resin layer 31 is uneven, the upper surface of the resin layer 31 is substantially flat.

A predetermined region of the resin layer 31 is exposed to light and then developed to form a plurality of via holes. For example, one via hole 31H exposes a portion of the wiring line 35 connected to the lower electrode layer 20L of the capacitor 20 via the contact electrode 20C. After the via holes are formed, heat treatment is performed to cure the semi-cured resin layer 31.

As shown in FIG. 6B, the wiring lines 36 of the second layer are formed on the resin layer 31 of the first layer. The wiring lines 36 of the second layer may be formed by a semi-additive method similar to the semi-additive method used to form the wiring lines 35 of the first layer.

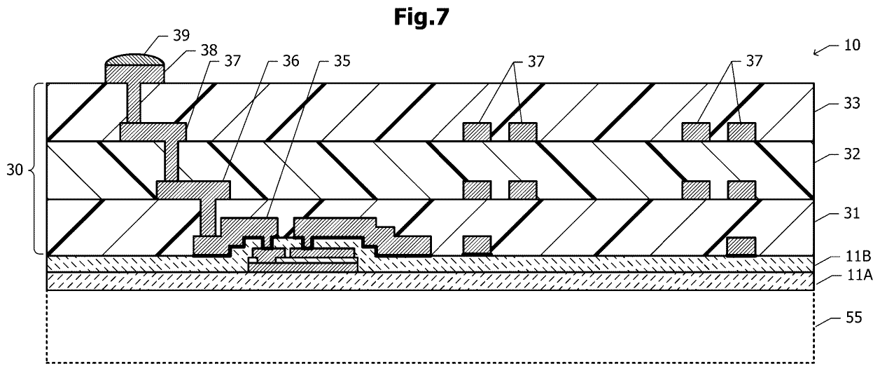

As shown in FIG. 7, the resin layer 32 of the second layer, the wiring lines 37 of the third layer, the resin layer 33 of the third layer, and the outer connection terminals 38 are formed. The resin layers 32 and 33 may be formed by a vacuum laminating method, and the wiring lines 37 and the outer connection terminals 38 may be formed by a semi-additive method. The solders 39 are placed on the upper surface of the outer connection terminals 38.

Thereafter, the temporary substrate 55 is removed in a state in which the upper surface of the resin layer 33 of the third layer and the outer connection terminal 38 are protected by an adhesive tape or the like. In FIG. 7, the temporary substrate 55 to be removed is indicated by a broken line. After the temporary substrate 55 is removed, the integrated passive component 10 is divided into individual pieces, and the adhesive tape used for protection is peeled off to thereby complete the integrated passive component 10 shown in FIG. 2. The temporary substrate 55 may be removed by wet etching using tetramethylammonium hydroxide (TMAH) or the like. Alternatively, the temporary substrate 55 may be removed by grinding or polishing a portion of the temporary substrate 55 and then etching the remaining portion of the temporary substrate 55. For example, when the thickness of the temporary substrate 55 is 700 μm, the temporary substrate 55 may be removed by grinding or polishing a portion having a thickness of 500 μm, and then etching the remaining portion having a thickness of 200 μm.

Next, excellent effects of the first embodiment will be described. In a configuration in which the temporary substrate 55 (see FIG. 7) is not removed, a thermal stress is generated due to a difference between the coefficient of linear expansion of the resin layers 31, 32 and 33 and the coefficient of linear expansion of the temporary substrate 55. For example, the coefficient of linear expansion of a resin such as polyimide or epoxy is about 20 ppm/° C. or more and 65 ppm/° C. or less (i.e., from 20 ppm/° C. to 65 ppm/° C.). In contrast, the coefficient of linear expansion of single crystal silicon used for the temporary substrate 55 is about 3 ppm/° C. The thermal stress tends to cause cracks in the resin layers 31, 32 and 33, and cause peeling at the interface between the insulating film 11 and the resin layer 31. When the cracks and peeling occur, the moisture resistance deteriorates and the quality of the integrated passive component 10 deteriorates.

In particular, when the thickness of the wiring lines 35, 36 and 37 and the resin layers 31, 32 and 33 is increased and the number of layers of the multilayer wiring structure 30 is increased for the purpose of improving the electrical characteristics of the integrated passive component 10, the cracks and peeling are more likely to occur. In the first embodiment, since the temporary substrate 55 is removed, the thermal stress is less likely to occur. As a result, the cracks and peeling are less likely to occur, and the quality deterioration of the integrated passive component 10 can be suppressed.

In particular, when the thickness of the resin layers 31, 32 and 33 and the thickness of the wiring lines 35, 36 and 37 of the multilayer wiring structure 30 are increased, a remarkable effect of employing a structure in which the temporary substrate 55 is removed can be obtained. For example, when the thickness of each of the resin layers 31, 32 and 33 is 10 μm or more, and the thickness of each of the wiring lines 35, 36 and 37 is 5 μm or more, a remarkable effect can be obtained. Further, in order to improve the electrical characteristics of the integrated passive component 10, it is more preferable that the thickness of each of the resin layers 31, 32 and 33 is 20 μm or more, and the thickness of each of the wiring lines 35, 36 and 37 is 10 μm or more. It should be noted that even if the resin layers 31, 32 and 33 and the wiring lines 35, 36 and 37 are made thicker than necessary, there is almost no further improvement in the electrical characteristics, but on the contrary, the difficulty of manufacture increases. Therefore, the thickness of each of the resin layers 31, 32 and 33 is preferably 30 μm or less, and the thickness of each of the wiring lines 35, 36 and 37 is preferably 15 μm or less.

When the lower insulating film 11A and the upper insulating film 11B, which are made of an inorganic insulating material, are made thicker, the thermal stress caused by the difference between the coefficient of linear expansion of the insulating film 11 and the coefficient of linear expansion of the resin layers 31, 32 and 33 becomes apparent. In order to prevent the influence of thermal stress caused by the difference between the coefficient of linear expansion of the insulating film 11 and the coefficient of linear expansion of the resin layers 31, 32 and 33 from being apparent, the thickness of the inorganic material layer included in the insulating film 11, i.e., the total thickness of the lower insulating film 11A and the upper insulating film 11B, is preferably smaller than the sum of the thickness of each of the plurality of resin layers 31, 32 and 33 of the multilayer wiring structure 30, and more preferably ½ or less of the sum of the thickness of each of the plurality of resin layers 31, 32 and 33 of the multilayer wiring structure 30.

When silicon nitride is used for the lower insulating film 11A, the moisture resistance of the integrated passive component 10 can be improved. When silicon oxide is used for the upper insulating film 11B, a general semiconductor microfabrication process can be applied in the step of forming the opening 11H (see FIG. 4C) in the upper insulating film 11B.

When the capacitor 20 is made too thick, the machining accuracy of the lower electrode layer 20L, the capacitor dielectric film 20D, and the upper electrode layer 20U deteriorates, and the accuracy of the capacitance deteriorates. In order to suppress the deterioration in the accuracy of the capacitance of the capacitor 20, the total thickness of the lower electrode layer 20L, the capacitor dielectric film 20D, and the upper electrode layer 20U is preferably 2 μm or less. In order to suppress the deterioration in the accuracy of the capacitance of the capacitor 20 and to suppress the deterioration in the characteristics of the inductor 40, the minimum value of the thickness of each of the plurality of wiring lines 35, 36 and 37 constituting the inductor 40 is preferably greater than the thickness of the thicker one of the lower electrode layer 20L and the upper electrode layer 20U of the capacitor 20, and more preferably 5 times or more than the thickness of the thicker one of the lower electrode layer 20L and the upper electrode layer 20U of the capacitor 20. By increasing the thickness of the plurality of wiring lines 35, 36 and 37 constituting the inductor 40, the electrical resistance of the wiring lines can be reduced.

In addition, when the number of layers of the multilayer wiring structure 30 increases, a remarkable effect of employing a configuration in which the temporary substrate 55 is removed can be obtained. In particular, when the number of layers of the multilayer wiring structure 30 is 3 or more, a remarkable effect can be obtained. In a configuration in which the number of layers of the multilayer wiring structure 30 is 3 or more, the electrical characteristics of inductor can be improved by disposing the plurality of wiring lines 35, 36 and 37 constituting the inductor 40 over 3 or more wiring layers. Further, as compared with a configuration in which the plurality of wiring lines 35, 36 and 37 constituting the inductor 40 are disposed over 2 or less wiring layers, the design inductance value per unit area can be increased.

When the distance in the stacking direction between the two wiring lines 35 and 36 adjacent to each other in the stacking direction and the two wiring lines 36 and 37 adjacent to each other in the stacking direction of the multilayer wiring structure 30 is shortened, the characteristics of the inductor 40 deteriorate due to the influence of the parasitic capacitance between the wiring lines. In order to suppress the deterioration of the characteristics of the inductor 40, it is preferable that the minimum value of the distance in the stacking direction between the wiring lines adjacent to each other in the stacking direction (i.e., the distance in the stacking direction between the wiring line 35 and the wiring line 36, and the distance in the stacking direction between the wiring line 36 and the wiring line 37) of the multilayer wiring structure 30 is equal to or greater than the maximum value of the thickness of each of the plurality of wiring lines 35, 36 and 37 constituting the inductor 40.

Alternatively, the present disclosure may include a configuration in which the distance in the stacking direction of a portion of the wiring lines adjacent to each other in the stacking direction of the multilayer wiring structure 30 is equal to or greater than the maximum value of the thickness of each of the plurality of wiring lines 35, 36 and 37 constituting the inductor 40. In such a case, deterioration in the characteristics of the inductor 40 due to the influence of parasitic capacitance between the wiring lines can also be suppressed to some extent.

### Second Embodiment

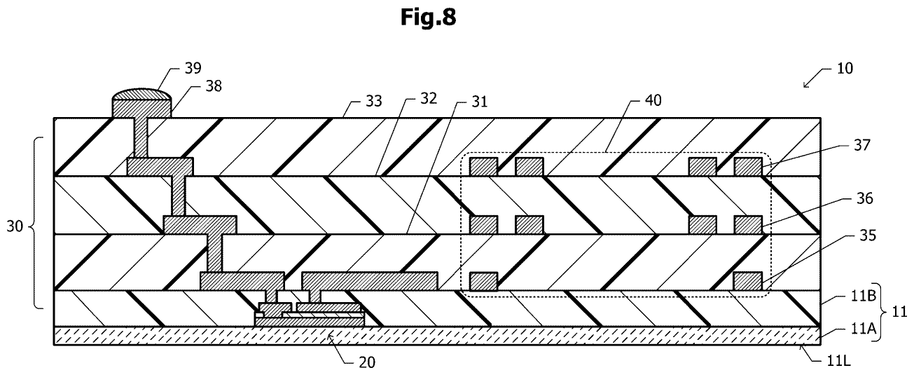

Next, an integrated passive component according to a second embodiment will be described with reference to FIG. 8. Hereinafter, the description of configurations common to the integrated passive component according to the first embodiment described with reference to FIGS. 1A to 7 will be omitted.

FIG. 8 is a cross-sectional view of an integrated passive component 10 according to the second embodiment. In the first embodiment (see FIG. 2), the upper insulating film 11B is formed of an inorganic insulating material. In contrast, in the second embodiment, an upper insulating film 11B is formed of an organic insulating material such as an insulating resin material containing epoxy, polyimide, or the like as a main component. Note that the resin constituting the upper insulating film 11B may contain impurities. The upper insulating film 11B made of the organic insulating material can be formed, for example, by a coating method. In such a case, the upper surface of the upper insulating film 11B is substantially flat.

Next, excellent effects of the second embodiment will be described. In the second embodiment, as in the first embodiment, the occurrence of the cracks and peeling caused by the thermal stress can be suppressed, and deterioration of electrical characteristics can be suppressed.

Further, in the second embodiment, since the upper insulating film 11B is formed of an organic insulating material, it is easy to make the upper insulating film 11B thicker than in the first embodiment. As the upper insulating film 11B becomes thicker, the distance between a capacitor 20 and an inductor 40 in the stacking direction becomes longer. As a result, good electrical isolation between the passive elements can be obtained, and the eddy current loss of the inductor 40 can be reduced.

In the first embodiment (see FIG. 2), the thickness of the inorganic material layer of the insulating film 11 is equal to the total thickness of the lower insulating film 11A and the upper insulating film 11B. In the first embodiment, the thickness of the inorganic material layer, i.e., the total thickness of the lower insulating film 11A and the upper insulating film 11B, is preferably made smaller than the sum of the thickness of each of the plurality of resin layers 31, 32 and 33 of the multilayer wiring structure 30.

In contrast, in the second embodiment, the thickness of the inorganic material layer of an insulating film 11 is equal to the thickness of a lower insulating film 11A. Since the upper insulating film 11B is formed of an organic insulating material, the coefficient of linear expansion of the upper insulating film 11B is close to the coefficient of linear expansion of each of resin layers 31, 32 and 33. In order to reduce the influence of thermal stress, the thickness of the lower insulating film 11A, which is an inorganic material layer, is preferably made smaller than the sum of the thickness of each of the plurality of resin layers 31, 32 and 33 of a multilayer wiring structure 30.

### Third Embodiment

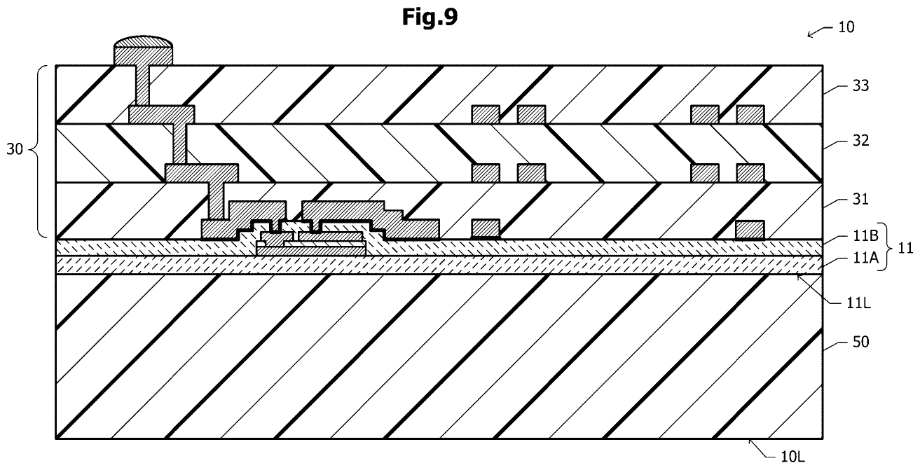

Next, an integrated passive component according to a third embodiment will be described with reference to FIG. 9. Hereinafter, the description of configurations common to the integrated passive component according to the first embodiment described with reference to FIGS. 1A to 7 will be omitted.

FIG. 9 is a cross-sectional view of an integrated passive component 10 according to the third embodiment. In the first embodiment (see FIG. 2), the lower surface 10L of the integrated passive component 10 is constituted by the second surface 11L of the insulating film 11. In contrast, in the third embodiment, a supporting member 50 made of an insulating material is adhered to a second surface 11L of an insulating film 11, and a lower surface 10L of the integrated passive component 10 is constituted by a surface of the supporting member 50 facing in the opposite direction to the surface adhered to the insulating film 11.

An insulating resin film is used as the supporting member 50. The supporting member 50 is adhered to the second surface 11L of the insulating film 11 due to the adhesiveness of the resin, for example. Alternatively, the supporting member 50 may also be adhered to the second surface 11L of the insulating film 11 using an adhesive. The difference between the coefficient of linear expansion of the supporting member 50 and the coefficient of linear expansion of each of a plurality of resin layers 31, 32 and 33 of a multilayer wiring structure 30 is smaller than the difference between the coefficient of linear expansion of the temporary substrate 55 (see FIG. 7) and the coefficient of linear expansion of each of the plurality of resin layers 31, 32 and 33 of the multilayer wiring structure 30. Generally, a single crystal silicon substrate is used as the temporary substrate 55. In such a case, the difference between the coefficient of linear expansion of the supporting member 50 and the coefficient of linear expansion of each of the plurality of resin layers 31, 32 and 33 of the multilayer wiring structure 30 is smaller than the difference between the coefficient of linear expansion of the single crystal silicon and the coefficient of linear expansion of each of the plurality of resin layers 31, 32 and 33 of the multilayer wiring structure 30.

Next, excellent effects of the third embodiment will be described. In the third embodiment, although the supporting member 50 is adhered to the second surface 11L of the insulating film 11, the difference between the coefficient of linear expansion of the supporting member 50 and the coefficient of linear expansion of each of the plurality of resin layers 31, 32 and 33 of the multilayer wiring structure 30 is smaller than the difference between the coefficient of linear expansion of the temporary substrate 55 (see FIG. 7) and the coefficient of linear expansion of each of the plurality of resin layers 31, 32 and 33 of the multilayer wiring structure 30. Therefore, the occurrence of the cracks and peeling caused by the thermal stress can be suppressed as compared with the configuration in which the temporary substrate 55 is left.

Further, since the supporting member 50 is adhered to the insulating film 11, the mechanical strength of the integrated passive component 10 can be improved as compared with the first embodiment. In order to obtain sufficient mechanical strength, the thickness of the supporting member 50 is preferably made greater than the thickness of the lower insulating film 11A.

In order to ensure sufficient heat dissipation through the supporting member 50, it is preferable to use a material having a thermal conductivity lower than the thermal conductivity of the lower insulating film 11A as the material of the supporting member 50. For example, it is preferable to use a material called a high thermal conductivity resin as the supporting member 50.

Next, a variation of the third embodiment will be described. In the third embodiment, an insulating resin is used for the supporting member 50, but an inorganic insulating material may be used instead. For example, ceramics, glass, or the like may be used for the supporting member 50. In such a case, it is also preferable that the difference between the coefficient of linear expansion of the supporting member 50 and the coefficient of linear expansion of each of the plurality of resin layers 31, 32 and 33 of the multilayer wiring structure 30 is smaller than the difference between the coefficient of linear expansion of the temporary substrate 55 (see FIG. 7) and the coefficient of linear expansion of each of the plurality of resin layers 31, 32 and 33 of the multilayer wiring structure 30.

### Fourth Embodiment

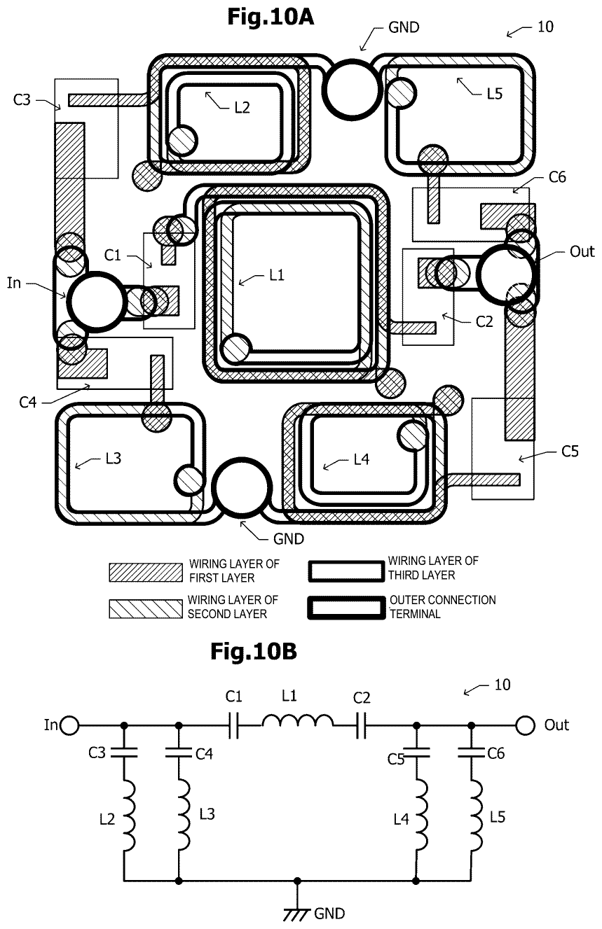

Next, an integrated passive component according to a fourth embodiment will be described with reference to FIGS. 10A and 10B. Hereinafter, the description of configurations common to the integrated passive component according to the first embodiment described with reference to FIGS. 1A to 7 will be omitted.

FIG. 10A is a diagram showing the shape and positional relationship of the components of an integrated passive component 10 according to the fourth embodiment in plan view, and FIG. 10B is an equivalent circuit diagram of the integrated passive component 10 according to the fourth embodiment. Similar to the integrated passive component 10 according to the first embodiment (see FIG. 1A), the integrated passive component 10 according to the fourth embodiment has capacitors, inductors, an input terminal In, an output terminal Out, a ground terminal GND, and a dummy terminal DMY, all these components being provided on a common insulating film. However, the integrated passive component 10 according to the fourth embodiment includes a plurality of capacitors C1, C2, C3, C4, C5 and C6 and a plurality of inductors L1, L2, L3, L4 and L5, and constitutes a band pass filter.

As shown in FIG. 10B, the capacitor C1, the inductor L1, and the capacitor C2 are connected in series between the input terminal In and the output terminal Out in this order from the side of the input terminal In. A series circuit of the capacitor C3 and the inductor L2 and a series circuit of the capacitor C4 and the inductor L3 are connected in parallel to each other between the input terminal In and the ground terminal GND. A series circuit of the capacitor C5 and the inductor L4 and a series circuit of the capacitor C6 and the inductor L5 are connected in parallel to each other between the output terminal Out and the ground terminal GND.

Similar to the capacitor 20 of the integrated passive component 10 according to the first embodiment (see FIG. 2), each of the plurality of capacitors C1, C2, C3, C4, C5 and C6 is composed of a lower electrode layer, a capacitor dielectric film, and an upper electrode layer. Note that the upper electrode layer may also be composed of two conductor patterns separated from each other, in which the two conductor patterns are used as a pair of electrode terminals of the capacitor. Similar to the inductor 40 of the integrated passive component 10 according to the first embodiment (see FIG. 2), each of the plurality of inductors L1, L2, L3, L4 and L5 is composed of a plurality of wiring lines in a multilayer wiring structure 30.

In FIG. 10A, the wiring line of the wiring layer of the first layer is indicated by relatively dense hatching slanted right upward, and the wiring line of the wiring layer of the second layer is indicated by relatively thin hatching slanted right downward. The outlines of outer connection terminals are indicated by the thickest solid lines, and the outline of each wiring line of the wiring layer of the third layer is indicated by a second thickest solid line.

The five inductors L1, L2, L3, L4 and L5, and the six capacitors C1, C2, C3, C4, C5 and C6 are disposed so as not to overlap with each other in plan view. The wiring lines constituting each of the inductors L1, L2 and L4 are disposed over three wiring layers. The wiring lines constituting each of the inductors L3 and L5 are disposed over two wiring layers.

Next, excellent effects of the fourth embodiment will be described. In the fourth embodiment, as in the first embodiment, the occurrence of the cracks and peeling caused by the thermal stress can be suppressed, and the deterioration of electrical characteristics can be suppressed. Further, as in the fourth embodiment, various passive circuits can be realized by disposing the plurality of capacitors and the plurality of inductors on the common insulating film 11.

Each of the embodiments described above is exemplary, and it goes without saying that partial substitution or combination of the configurations shown in the different embodiments is possible. Similar effects of similar configurations of the embodiments are not described sequentially for each embodiment. Further, the present disclosure is not limited to the embodiments described above. For example, it should be obvious to those skilled in the art that various modifications, improvements, combinations and the like can be made.

What is claimed is:

1. An integrated passive component having an upper surface and a lower surface facing in mutually opposite directions, the integrated passive component comprising:
an insulating film having a first surface and a second surface, the first surface facing in the same direction as the upper surface, the second surface facing in the same direction as the lower surface;
a capacitor in the insulating film; and
a multilayer wiring structure on the first surface of the insulating film,
wherein
the multilayer wiring structure includes a plurality of resin layers and a plurality of wiring layers, the plurality of resin layers and the plurality of wiring layers being alternately stacked, each of the plurality of wiring layers includes a plurality of wiring lines, and at least a portion of the plurality of wiring lines configures an inductor,
the insulating film includes an inorganic material layer including an inorganic insulating material, and a thickness of the inorganic material layer is smaller than a sum of a thickness of each of the plurality of resin layers of the multilayer wiring structure, and
the second surface of the insulating film configures the lower surface.

2. An integrated passive component having an upper surface and a lower surface facing in mutually opposite directions, the integrated passive component comprising:
an insulating film having a first surface and a second surface, the first surface facing in the same direction as the upper surface, the second surface facing in the same direction as the lower surface;
a capacitor in the insulating film;
a multilayer wiring structure on the first surface of the insulating film; and
a supporting member including an insulating resin and attached to the second surface of the insulating film,
wherein
the multilayer wiring structure includes a plurality of resin layers and a plurality of wiring layers, the plurality of resin layers and the plurality of wiring layers being alternately stacked, each of the plurality of wiring layers includes a plurality of wiring lines, and at least a portion of the plurality of wiring lines configures an inductor, and
the insulating film includes an inorganic material layer including an inorganic insulating material, and a thickness of the inorganic material layer is smaller than a sum of a thickness of each of the plurality of resin layers of the multilayer wiring structure.

3. The integrated passive component according to claim 2, wherein
the supporting member includes a resin including epoxy or polyimide as a main component.

4. The integrated passive component according to claim 2, wherein
a thermal conductivity of the supporting member is higher than a thermal conductivity of the inorganic material layer of the insulating film.

5. The integrated passive component according to claim 1, wherein
the plurality of wiring lines configuring the inductor are over three or more wiring layers among the plurality of wiring layers.

6. The integrated passive component according to claim 5, wherein
a distance in a stacking direction of at least a portion of wiring lines adjacent to each other in the stacking direction of the multilayer wiring structure is equal to or greater than a maximum value of a thickness of each of the plurality of wiring lines configuring the inductor.

7. The integrated passive component according to claim 1, wherein
the capacitor includes a lower electrode layer, an upper electrode layer on a side of the upper surface from the lower electrode layer, and a capacitor dielectric film between the lower electrode layer and the upper electrode layer, and
a minimum value of a thickness of each of the plurality of wiring lines configuring the inductor is greater than a thickness of a thicker one of the lower electrode layer and the upper electrode layer of the capacitor.

8. The integrated passive component according to claim 1, wherein
the plurality of wiring lines include Cu or an alloy including Cu as a main component.

9. The integrated passive component according to claim 1, wherein
the insulating film includes a lower insulating film having the second surface and an upper insulating film having the first surface,
the capacitor is between the lower insulating film and the upper insulating film, and
the upper insulating film includes silicon oxide.

10. The integrated passive component according to claim 1, wherein
the insulating film includes a lower insulating film having the second surface and an upper insulating film having the first surface,
the capacitor is between the lower insulating film and the upper insulating film, and
the upper insulating film includes a resin.

11. The integrated passive component according to claim 9, wherein
the lower insulating film includes silicon nitride.

12. A method of manufacturing an integrated passive component, comprising:
forming a lower insulating film on one surface of a temporary substrate made of a semiconductor;
forming a capacitor in a portion of a region of the lower insulating film;
forming an upper insulating film on the lower insulating film to cover the capacitor;
forming a multilayer wiring structure on the upper insulating film, the multilayer wiring structure including a plurality of resin layers and a plurality of wiring lines configuring an inductor, the plurality of resin layers and the plurality of wiring lines being alternately stacked; and
removing the temporary substrate to expose the lower insulating film.

13. The method of manufacturing an integrated passive component according to claim 12, further comprising:
after removing the temporary substrate, attaching an insulating supporting member to a surface of the exposed lower insulating film,
wherein a difference between a coefficient of linear expansion of the supporting member and a coefficient of linear expansion of each of the plurality of resin layers of the multilayer wiring structure is smaller than a difference between a coefficient of linear expansion of the temporary substrate and the coefficient of linear expansion of each of the plurality of resin layers of the multilayer wiring structure.

14. The integrated passive component according to claim 3, wherein
a thermal conductivity of the supporting member is higher than a thermal conductivity of the inorganic material layer of the insulating film.

15. The integrated passive component according to claim 2, wherein
the plurality of wiring lines configuring the inductor are over three or more wiring layers among the plurality of wiring layers.

16. The integrated passive component according to claim 2, wherein
the capacitor includes a lower electrode layer, an upper electrode layer on a side of the upper surface from the lower electrode layer, and a capacitor dielectric film between the lower electrode layer and the upper electrode layer, and
a minimum value of a thickness of each of the plurality of wiring lines configuring the inductor is greater than a thickness of a thicker one of the lower electrode layer and the upper electrode layer of the capacitor.

17. The integrated passive component according to claim 2, wherein
the plurality of wiring lines include Cu or an alloy including Cu as a main component.

18. The integrated passive component according to claim 2, wherein
the insulating film includes a lower insulating film having the second surface and an upper insulating film having the first surface,
the capacitor is between the lower insulating film and the upper insulating film, and
the upper insulating film includes silicon oxide.

19. The integrated passive component according to claim 2, wherein
the insulating film includes a lower insulating film having the second surface and an upper insulating film having the first surface,
the capacitor is between the lower insulating film and the upper insulating film, and
the upper insulating film includes a resin.

20. The integrated passive component according to claim 10, wherein
the lower insulating film includes silicon nitride.
